(19) United States
(12) Patent Application Publication
(10) Pub. No.: US 2026/0255722 A1
(43) Pub. Date: Aug. 27, 2026

(54) LAYER STACK, METHOD AND PROCESS SYSTEM

(71) Applicant: VON ARDENNE Asset GmbH & Co. KG, Dresden (DE)

(72) Inventors: Eric Schneiderloechner, Dresden (DE); Volker Linss, Dresden (DE); Tina Dietsch, Dresden (DE)

(21) Appl. No.: 19/176,259

(22) Filed: Apr. 11, 2025

(30) Foreign Application Priority Data
Feb. 25, 2025 (EP) 25160119.1

(51) Int. Cl. H10F 77/30; C23C 28/04; H10F 10/164

(52) U.S. Cl. CPC H10F 77/315; C23C 28/04; H10F 10/164

(57) ABSTRACT

According to various aspects, a layer stack comprises: a carrier layer; one or more passivation layers formed by a physical vapor deposition process, preferably comprising a first passivation layer and/or a second passivation layer, for each of the one or more passivation layers, a metal oxide containing protection layer formed by a chemical vapor deposition process between the passivation layer and the carrier layer.

### CROSS-REFERENCE TO RELATED APPLICATION

This Patent Application claims priority from European Patent Application No. 25160119.1 filed on Feb. 25, 2025 according to 35 U.S.C. § 119, the entire disclosure of which is incorporated herein by reference and for all purposes.

### TECHNICAL FIELD

Various aspects relate generally to a layer stack, a method and a process system.

### BACKGROUND

Since the development and commercialization of solar cells for energy generation, various key optimization parameters include the efficiency to produce electric energy from sunlight and production costs. In this light, various solar cell technologies have been developed to increase efficiency without increasing the production costs, among which the PERC technology (“Passivated Emitter and Rear Cell”) and the TOPCon technology lead the market. For PERC technology, a rear side passivation is used provided by a dielectric thin film, which increases the light yield. However, the remaining recombination losses at the metallic contacts that penetrate the rear side passivation of PERC still significantly limit the efficiency. A passivated contact is used as a further advancement of the PERC technology, which reduces these recombination losses. This passivated contact is characterized by the fact that the contact (e.g., the metallization) is dielectrically separated from the semiconductor junction of the solar cell. In a favored implementation, the passivated contact is provided by a tunnel oxide passivated contact (TOPCon), which promises an efficiency of more than 24%, for example for a silicon-based solar cell.

### BRIEF DESCRIPTION OF THE DRAWINGS

Throughout the drawings, it should be noted that like reference numbers are used to depict the same or similar elements, features, and structures. The drawings are not necessarily to scale, emphasis instead generally being placed upon illustrating aspects of the disclosure. In the following description, some aspects of the disclosure are described with reference to the following drawings, in which:

FIG. 1A to FIGS. 1D, 2A, 2B, 5B, and 6B respectively illustrate various architectures for implementing a solar cell according to various embodiments in various views;

FIGS. 3A, 3B, 4A, 4B, 5A, 6A illustrates a method according to various embodiments in a schematic flowchart;

FIG. 3C and FIG. 3D respectively illustrate a SCP according to various embodiments in various views; and

FIG. 7A and FIG. 7B respectively illustrate a process system for forming the layer stack according to various embodiments in various views.

### DESCRIPTION

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and electrical changes may be made without departing from the scope of the disclosure. The various aspects are not necessarily mutually exclusive, as some aspects may be combined with one or more other aspects to form new aspects. Various aspects are described in connection with methods and various aspects are described in connection with devices. However, it may be understood that aspects described in connection with methods may similarly apply to the devices, and vice versa. Throughout the drawings, it should be noted that like reference numbers are used to depict the same or similar elements, features, and structures.

In the following, various examples are provided with reference to the aspects and implementations detailed herein.

Example 1 is configured in accordance with one of the accompanying claims and/or is a layer stack, comprising: a carrier layer (e.g., including or provided by a substrate); one or more passivation layers formed by a physical vapor deposition process, e.g., comprising a first passivation layer and/or a second passivation layer, and, for each of the one or more passivation layers, a metal oxide containing protection layer formed by a chemical vapor deposition process between the passivation layer and the carrier layer.

Example 2 is a method for forming a layer stack (e.g., according to example 1), the method comprising: forming one or more passivation layers by a physical vapor deposition process, e.g., comprising a first passivation layer and/or a second passivation layer, over a carrier layer (e.g., including or provided by a substrate); optionally forming, for each of the one or more passivation layers and/or by a chemical vapor deposition process (e.g., by ALD or PECVD), a metal oxide containing protection layer between the passivation layer and the carrier layer. Optionally, the method includes, e.g., when the carrier layer is coated by one or more protection layers, exposing the one or more protection layer to an outgassing process, e.g., prior to forming the one or more passivation layers, which, preferably, include one passivation for each of the one or more protection layers, which is disposed between the passivation layer and the carrier layer.

Example 3 is a process system, comprising: multiple process devices (e.g., physical vapor deposition process devices); one or more vacuum chambers, in which the multiple process devices are disposed; a transport device configured for transporting a substrate providing a carrier layer (e.g., including or provided by the substrate) through the one or more vacuum chambers; wherein the multiple (e.g., physical vapor deposition) process devices are configured to provide a process sequence resulting in the layer stack according to example 1 and/or implementing the method according to example 2.

Example 4 is a usage of a process system, comprising multiple (e.g., physical vapor deposition) process devices and one or more vacuum chambers, in which the multiple (e.g., physical vapor deposition) process devices are disposed, for forming the layer stack according to example 1 and/or for implementing the method according to example 2 based on a substrate providing the carrier layer, which is transported by a transport device through the one or more vacuum chambers.

Example 5 is an electronic device (e.g., a solar cell), comprising: a (e.g., photovoltaic) carrier layer comprising a bipolar semiconductor junction; a (e.g., tunnel) dielectric layer (e.g., a tunnel oxide layer and/or formed by a physical vapor deposition process); one or more passivation layers formed by a physical vapor deposition process and comprising a first passivation layer and/or a second passivation layer, wherein, preferably, the carrier layer is disposed between the first passivation layer and the dielectric layer and/or wherein the dielectric layer is disposed between the second passivation layer and the carrier layer.

Example 6 is a method for forming an electronic device (e.g., according to example 5), the method comprising: forming a (e.g., tunnel) dielectric layer (e.g., a tunnel oxide layer) by a physical vapor deposition process; forming one or more passivation layers by a physical vapor deposition process and comprising a first passivation layer and/or a second passivation layer, wherein a carrier layer (e.g., including or provided by a substrate) of the layer stack is disposed between the first passivation layer and the dielectric layer and/or wherein the dielectric layer is disposed between the second passivation layer and the carrier layer.

Example 7 is a process system, comprising: multiple (e.g., physical vapor deposition) process devices; one or more vacuum chambers, in which the multiple (e.g., physical vapor deposition) process devices are disposed; a transport device configured for transporting a substrate providing a carrier layer (e.g., including or provided by a substrate) through the one or more vacuum chambers; wherein the multiple process devices are configured to provide a process sequence (a sequence of multiple processes) resulting in the electronic device according to example 5 and/or implementing the method according to example 6.

Example 8 is a usage of a process system, comprising multiple (e.g., physical vapor deposition) process devices and one or more vacuum chambers, in which the multiple process devices are disposed, for forming the layer stack according to example 5 and/or for implementing the method according to example 6 based on a substrate providing the carrier layer, which is transported by a transport device through the one or more vacuum chambers.

Example 9 is a usage of a metal oxide containing protection layer (e.g., to provide one of the examples 1 to 8) formed by a chemical vapor deposition process between a passivation layer and a carrier layer (e.g., including or provided by a substrate), e.g., to protect the carrier layer when forming the passivation layer by a physical vapor deposition process (e.g., on the metal oxide containing protection layer).

Example 10 is configured in accordance with one of examples 1 to 9, including, for the first passivation layer formed by PVD process, a first protection layer formed by CVD process (e.g., ALD or PECVD) between the first passivation layer and the carrier layer.

Example 11 is configured in accordance with one of examples 1 to 10, including, for the second passivation layer formed by PVD process, a second protection layer formed by CVD process (e.g., ALD or PECVD) between the second passivation layer and the carrier layer.

Example 12 is configured in accordance with one of examples 1 to 11, wherein the dielectric layer (e.g., a tunnel dielectric layer, e.g., a tunnel oxide layer), the second protection layer and/or the second passivation layer are disposed on a rear side of the carrier layer.

Example 13 is configured in accordance with one of examples 1 to 12, wherein the first passivation layer and/or the first protection layer are disposed on a front side of the carrier layer.

Example 14 is configured in accordance with one of examples 1 to 13, wherein the first passivation layer and/or the second passivation layer comprise or consist of a nitride, e.g., a semiconductor nitride, e.g., silicon nitride.

Example 15 is configured in accordance with one of examples 1 to 14, wherein the first passivation layer and/or the second passivation layer comprise a semiconductor material of the carrier layer.

Example 16 is configured in accordance with one of examples 1 to 15, wherein the dielectric layer (e.g., a tunnel dielectric layer, e.g., tunnel oxide layer) comprises a semiconductor material of the carrier layer.

Example 17 is configured in accordance with one of examples 1 to 16, wherein the physical vapor deposition process comprises a sputtering process and/or uses a plasma.

Example 18 is configured in accordance with one of examples 1 to 17, comprising one or more metal oxide (e.g., aluminum oxide) containing protection layers formed by chemical vapor deposition process (e.g., atomic layer deposition-ALD, or PECVD), preferably comprising a first metal oxide containing protection layer and/or a second metal oxide containing protection layer.

Example 19 is configured in accordance with one of examples 1 to 18, wherein the first metal oxide containing protection layer is preferably disposed between the carrier layer and the first passivation layer and/or wherein the second metal oxide containing protection layer is preferably disposed between the carrier layer and the dielectric layer (e.g., a tunnel oxide layer).

Example 20 is configured in accordance with one of examples 1 to 19, wherein the first passivation layer and/or the second passivation layer comprise hydrogen, e.g., being doped by hydrogen.

Example 21 is configured in accordance with one of examples 1 to 20, wherein the carrier layer comprises a semiconductor material (e.g., silicon) and/or a stack of two sublayers differing from each other by a type of doping (e.g., providing the semiconductor junction).

Example 22 is configured in accordance with one of examples 1 to 21, further comprising a (e.g., tunnel) dielectric layer (e.g., a tunnel oxide layer), e.g., formed by a physical vapor deposition process and/or between the second protection layer and the carrier layer.

Example 23 is configured in accordance with one of examples 1 to 22, wherein the carrier layer is disposed between the first passivation layer and the dielectric layer (e.g., a tunnel oxide layer); and/or wherein the dielectric layer is disposed between the second passivation layer and the carrier layer.

Example 24 is configured in accordance with one of examples 1 to 23, wherein the carrier layer is disposed between the first passivation layer and the second passivation layer.

Example 25 is configured in accordance with one of examples 1 to 24, wherein the carrier layer comprises a front side and a rear side.

Example 26 is configured in accordance with one of examples 1 to 25, wherein the carrier layer comprises a bipolar semiconductor junction.

Example 27 is configured in accordance with one of examples 1 to 26, wherein the carrier layer is a photovoltaic carrier layer.

Example 28 is configured in accordance with one of examples 1 to 27, being implemented without usage of silane and/or phosphine (e.g., supplied to a chemical vapor deposition process).

Example 29 is configured in accordance with one of examples 1 to 28, being implemented without usage of methane and/or nitrogen oxide (e.g., supplied to a chemical vapor deposition process).

Example 30 is configured in accordance with one of examples 1 to 29, further comprising one or more outgassing (e.g., moisture and/or hydrogen depletion) processes (HDP), including: a first HDP, to which the first metal oxide containing protection layer (e.g., prior to forming the first passivation layer) and/or the first passivation layer are exposed; and/or a second HDP, to which the second metal oxide containing protection layer (e.g., prior to forming the second passivation layer) and/or the second passivation layer are exposed.

Example 31 is configured in accordance with example 30, wherein the or each HDP is configured to reduce a content of hydrogen of the (e.g., first and/or second) metal oxide containing protection layer and/or of the (e.g., first and/or second) passivation layer.

Example 32 is configured in accordance with example 30 or 31, wherein the or each HDP is configured to deplete (e.g., outgas) hydrogen from the (e.g., first and/or second) metal oxide containing protection layer and/or of the (e.g., first and/or second) passivation layer.

Example 33 is configured in accordance with one of examples 30 to 32, wherein the wherein the or each HDP comprises an annealing process, to which the (e.g., first and/or second) metal oxide containing protection layer and/or of the (e.g., first and/or second) passivation layer are exposed. As example, the annealing process includes heating to a temperature above 100° C. (e.g., above 200°°C., e.g., above 300° C.) Example 34 is configured in accordance with one of examples 30 to 33, wherein the wherein the or each HDP comprises exposing the (e.g., first and/or second) metal oxide containing protection layer and/or of the (e.g., first and/or second) passivation layer to a high vacuum and/or to a plasma.

Example 35 is configured in accordance with one of examples 1 to 34, wherein the layer stack is formed without usage of silane and/or phosphine (e.g., supplied to a chemical vapor deposition process).

Example 36 is configured in accordance with one of examples 1 to 35, wherein the layer stack is formed without usage of a (e.g., plasma enhanced) chemical vapor deposition process.

Example 37 is configured in accordance with one of examples 1 to 36, wherein the layer stack is formed without usage of methane and/or nitrogen oxide (e.g., supplied to a chemical vapor deposition process).

Example 38 is configured in accordance with one of examples 1 to 37, wherein the solar cell is a tunnel oxide passivated contact based solar cell.

Example 39 is configured in accordance with one of examples 1 to 38, comprising, for each of the one or more passivation layers, a metal oxide containing protection layer formed by a physical vapor deposition process between the passivation layer and the carrier layer.

Example 40 is configured in accordance with one of examples 1 to 39, comprising one or more bilayers, of which each bilayer comprises one of the (e.g., hydrogen containing) passivation layer and one of the metal oxide containing protection layer, be being in physical contact with each other.

Example 41 is configured in accordance with one of examples 1 to 40, wherein the first protection layer is in physical contact with the carrier layer and/or with the passivation layer.

Example 42 is configured in accordance with one of examples 1 to 41, wherein the second protection layer is in physical contact with the carrier layer or with a passivated contact provided by the tunnel dielectric layer (e.g., TO layer).

Example 43 is configured in accordance with one of examples 1 to 42, wherein the (e.g., one or more) passivation layer include hydrogen (also referred to as hydrogen containing passivation layer), e.g., being doped by hydrogen, and/or is formed in a hydrogen containing atmosphere. For example, the hydrogen containing atmosphere may include ammonia, molecular hydrogen and/or (e.g., molecular) nitrogen.

Example 44 is configured in accordance with one of examples 1 to 43, wherein the first metal oxide containing protection layer and/or the second metal oxide containing protection layer include (e.g., consists) of aluminum oxide.

Example 45 is an electronic device (e.g., solar cell) including the layer stack one of examples 1 to 44.

Example 46 is configured in accordance with one of examples 1 to 45, wherein the dielectric layer is a tunnel dielectric layer (e.g., tunnel oxide layer) and/or formed by a physical vapor deposition process.

Example 47 is configured in accordance with one of examples 1 to 46, wherein the substrate is a solar cell precursor (also referred to as SCP) and/or includes a semiconductor wafer.

Example 48 is configured in accordance with one of examples 1 to 47, wherein the carrier layer includes multiple sublayers (e.g., a core sublayer and an emitter sublayer) differing from each other in the type of doping. The core sublayer may provide a base sublayer of a solar cell.

Example 49 is configured in accordance with one of examples 1 to 48, wherein the first protection layer is disposed between the emitter sublayer of carrier layer (e.g., physically contacting the same) and the first passivation layer (e.g., physically contacting the same).

Example 50 is configured in accordance with one of examples 1 to 49, wherein the second protection layer is disposed between the tunnel dielectric layer and the second passivation layer (e.g., physically contacting the same).

Example 51 is configured in accordance with one of examples 1 to 50, wherein the or each passivation layer provides an anti-reflection layer and/or is transparent.

Example 52 is configured in accordance with one of examples 1 to 51, wherein the or each dielectric layer (e.g., tunnel dielectric layer) is thinner than the protection layer and/or thinner than the passivation layer.

Example 53 is configured in accordance with one of examples 1 to 52, wherein a thickness of the or each passivation layer is less than 500 nm (e.g., less than 200 nm, e.g., less than 150 nm) and/or more than 10 nm (e.g., than 20 nm, e.g., than 40 nm), e.g., in the range between 60 nm (Nanometer) and 120 nm, preferably in the range between 65 (e.g., 70) nm and 80 (e.g., 75) nm. As example, the thickness of the passivation layer containing hydrogenated silicon nitride is 50-120 nm, preferably 65-80 nm.

Example 54 is configured in accordance with one of examples 1 to 53, wherein a refractive index of the or each passivation layer is in the range between 1.8 and 2.2, preferably between 2.0 and 2.1 (e.g., 2.05).

Example 55 is configured in accordance with one of examples 1 to 54, wherein the layer stack (e.g., the electric device) is free of pin marks. This indicates that the layer stack (e.g., the electric device), e.g., the carrier layer thereof, was not contacted by contact pin, and thereby indicates formation by a PVD process (e.g., rather than PECVD process).

Example 56 is configured in accordance with one of examples 1 to 55, wherein the protection layer includes a line-shaped region, which extends (e.g., along a closed path) along a rim of the protection layer (e.g., on the rear side thereof), and in which the protection layer is exposed and/or which protrudes from the passivation layer. This indicates that a holding frame was used during film formation, and thereby indicates formation by a PVD process (e.g., rather than PECVD process).

Example 57 is configured in accordance with one of examples 1 to 56, wherein a thickness of the tunnel dielectric (e.g., oxide) layer is less than 20 nm (Nanometer), e.g., less than 10 nm, e.g., less than 5 nm, e.g., less than 2 nm, and/or less than a thickness of one or more of: the passivation layer and/or the protection layer. As example, the thickness of the SiOx containing tunnel oxide layer is 0.5-2 nm, preferably 1-1.5 nm.

Example 58 is configured in accordance with one of examples 1 to 57, wherein a thickness of the protection layer is less than 100 nm (e.g., less than 50 nm, e.g., less than 20 nm, e.g., less than 10 nm) and/or less than a thickness of the passivation layer. Alternatively or additionally, the thickness of the protection layer is more than 2 nm (e.g., than 5 nm, e.g., than 10 nm, e.g., than 20 nm) and/or more than the thickness of the tunnel oxide layer. As example, the thickness of the protection layer is 1-10 nm, preferably 3-6 nm.

Example 59 is configured in accordance with one of examples 1 to 58, wherein the or each passivation layer includes or consists of a dielectric layer (then also referred to as dielectric passivation layer).

Example 60 is configured in accordance with one of examples 1 to 59, wherein the passivation layer and/or the protection layer are transparent and/or differ from each other in a refractive index.

Example 61 is configured in accordance with one of examples 1 to 60, wherein the or each protection layer includes or consists of a dielectric layer (then also referred to as dielectric protection layer).

Example 62 is configured in accordance with one of examples 1 to 61, wherein the PVD process includes exposing one or more (e.g., ceramic and/or dielectric) targets to a plasma, e.g., for forming the or each protection layer, wherein, preferably the or each target is tubular and/or is rotated, while being exposed to the plasma.

Example 63 is configured in accordance with one of examples 1 to 62, wherein a thickness of the transfer layer (e.g., polySi layer) is less than a thickness of the carrier layer and/or more than a thickness of the second passivation layer.

Example 64 is configured in accordance with one of examples 1 to 63, wherein a thickness of the transfer layer is less than 500 nm (e.g., less than 200 nm, e.g., less than 150 nm) and/or more than 10 nm (e.g., than 20 nm, e.g., than 40 nm), e.g., in the range between 60 nm (Nanometer) and 120 nm, preferably in the range between 70 nm and 95 nm.

Example 65 is configured in accordance with one of examples 1 to 64, wherein the outgassing process is configured to reduce a hydrogen content, e.g., by depleting one or more hydrogen containing agents (e.g., atomic hydrogen, molecular hydrogen and/or a chemical compound including hydrogen) and/or by exposure to a plasma (e.g., under vacuum and/or formed in a vacuum chamber).

Example 66 is configured in accordance with one of examples 1 to 65, wherein the multiple process devices include: one or more physical vapor deposition devices (e.g., sputtering devices) and/or one or more outgassing devices (e.g., configured to perform the outgassing process). For example, each physical vapor deposition device is coating device configured to perform a PVD process. For example, each outgassing device is configured to provide a plasma and/or includes a resistive heating device.

Example 67 is configured in accordance with one of examples 1 to 66, wherein forming the layer stack (e.g., by the process system) may include processing a device precursor (e.g., SCP), wherein the device precursor includes: the carrier layer, and one or more metal oxide containing protection layers.

Example 68 is configured in accordance with one of examples 1 to 67, wherein the one or more metal oxide containing protection layers include, for example, a metal oxide containing first protection layer formed over the carrier layer (e.g., over a front side of the carrier layer) and/or formed by CVD (e.g., ALD or PECVD).

Example 69 is configured in accordance with one of examples 1 to 68, wherein the one or more metal oxide containing protection layers may include, for example, a metal oxide containing second protection layer formed over the carrier layer (e.g., over a rear side of the carrier layer) and/or formed by CVD (e.g., ALD or PECVD).

Example 70 is configured in accordance with one of examples 1 to 69, wherein processing the device precursor may include forming the first passivation layer on (e.g., directly in contact with) the first protection layer, e.g., by PVD.

Example 71 is configured in accordance with one of examples 1 to 70, wherein processing the device precursor may include forming the second passivation layer on (e.g., directly in contact with) the second protection layer, e.g., by PVD.

Example 72 is configured in accordance with one of examples 1 to 71, the passivation layer is formed using one or more than one tubular (e.g., magnetron) target, which preferably includes silicon and optionally a dopant of silicon (e.g., one or more than one of: phosphorus, boron, arsenic, and/or gallium).

Example 73 is configured in accordance with example 72, wherein a purity of the one or more than one magnetron targets is 3.5N or more (e.g. 4N or more, e.g., 4.5N or more), and/or 5N or less.

Example 74 is configured in accordance with example 72 or 73, wherein the more than one tubular target includes two targets, which are provided by a dual magnetron sputtering device.

Example 75 is configured in accordance with one of examples 72 to 74, wherein the one or more than one targets are exposed to an alternating voltage (also referred to as AC voltage), wherein a frequency of the alternating voltage (e.g., a sine wave voltage) is within a medium frequency range (e.g., between 100 kHz and 3000 kHz) and/or the alternating voltage is a bipolar alternated voltage (e.g., square wave voltage).

Example 76 is configured in accordance with one of examples 72 to 75, wherein a distance of the one or more than one target from the carrier layer is in the range from 80 mm (millimeter) to 150 mm.

Example 77 is configured in accordance with one of examples 72 to 76, wherein the or each target is supplied by an electrical power in the range from 5 kW (Kilowatt) to 15 kW, e.g., per meter of the target. For example, the length of the target (along the rotation axis) may be L, wherein the electrical power is in the range of L times P, wherein P is in the range from 5 kW (Kilowatt) to 15 kW.

Example 78 is configured in accordance with one of examples 1 to 77, wherein the one or more than one target and/or the passivation layer are exposed to a process gas, which includes one or more than one of: nitrogen, hydrogen, argon, argon hydrogen, krypton, ammonia.

Example 79 is configured in accordance with one of examples 1 to 78, wherein the one or more than one target and/or the passivation layer are exposed to a pressure (e.g., of the process gas) in the range from lubar to 3 μbar (1E-3 mbar bis 3E-3 mbar).

Example 80 is configured in accordance with one of examples 1 to 79, wherein the one or more than one target and/or the passivation layer are exposed to a hydrogen conten (e.g., of the process gas) in the range from 10% to 20%; and/or wherein each passivation layer has a hydrogen content (e.g., of the process gas) in the range from 10% to 20%.

Example 81 is configured in accordance with one of examples 1 to 80, wherein the carrier layer and/or the protection layer is exposed (e.g., brought to a) temperature in the range of 200° C. to 350° C.

Example 82 is configured in accordance with one of examples 1 to 81, wherein a thickness of the passivation layer is in the range from 50 nm (Nanometer) to 500 nm, e.g., in the range from 60-100 nm (e.g., 70-80 nm) for the front side of the SCP and/or in the range from 80-130 nm (e.g., 100-110 nm) for the rear side of the SCP.

According to various embodiments, reference is made to multiple layers (e.g., forming a layer stack), their arrangement relative to each other, e.g., expressed as sequence and/or expressed by spatial prepositions (e.g., over, under, between, etc.). It may be understood that a stack of layers may include two or more layers, which are disposed over each other. It may be understood that adjacent layers of the multiple layers, as detailed herein, may, in some aspects, be in physical contact with each other, or may, in some other aspects, be spatially separated from each other, e.g., by one or more other layers of the multiple layers in between them.

According to various embodiments, a process is provided that improves the economic efficiency of the manufacture of solar cells or facilitates their manufacture. It was clearly recognized that the majority of the hurdles explained herein may be overcome by using, among other things, physical vapor deposition process (PVD process), preferably sputtering, for example in combination with a holding frame and/or a low coating temperature. These measures clearly improve the layer properties, for example with regard to stoichiometry, the use of toxic volatile substances and/or the tendency to form edge wrap. The lower coating temperature, for example, helps to save energy, inhibits the formation of toxic volatile substances and reduces the risk of the formed layer flaking off.

According to various embodiments, a vacuum arrangement (e.g. vacuum system) is further provided for layer silicon wafers with a layer stack to produce a (e.g., TOPCon or PERC) solar cell by a PVD process (for example, for mass production of silicon solar cells with passivated contacts). For example, various layer of solar cell may be formed by PVD process, among others ARC (e.g., provided by a passivation layer), a tunnel dielectric layer and/or a doped polycrystalline silicon layer. The desired dopant in the silicon layer, for example phosphorus in the n-doped case, may then also be driven in during the subsequent high-temperature step in order to produce a polycrystalline silicon layer from the deposited amorphous or semi-crystalline silicon layer. This results in the desired electrically conductive layer stack for the formation of a passivated contact (then referred to as TOPCon).

With respect to the chemical compounds explained herein, such as oxides, carbides and/or nitrides, it may be understood that these may be stoichiometric or sub-stoichiometric (i.e. having vacancies). For example, substoichiometric silicon oxide may be indicated as SiO_{2-y} (y>0 and/or y<1), or shorter expressed as SiOₓ (x=2−y). An amorphous material is indicated by “a” or “a-”, e.g., “aSi” or “a-Si” for amorphous silicon. A polycrystalline material is indicated by “poly” or “poly-”, e.g., “polySi” or “poly-Si” for polycrystalline silicon. A hydrogen containing material (also referred to as hydrogenated materials) is indicated by “: H”, e.g., “SiNx: H” for hydrogenated semiconductor nitride, e.g., silicon nitride.

Reference is made herein to a method and a vacuum arrangement (e.g. a vacuum system thereof), which is for example adapted to carry out the method, in connection with processing a solar cell precursor (also referred to as a solar cell substrate or as partially processed solar cell, or short as SCP) as an exemplary substrate. It may be understood that what is described for the SCP may apply to any other substrate which is coated with one or more than one dielectric, preferably of an oxide (e.g. semiconductor oxide, e.g. silicon oxide). With respect to the layer and/or with respect to the processing, it may further be understood that what is described for a specific side (e.g. rear or front) of the SCP (or substrate) may apply by analogy to the respective opposite side (then front or back) of the SCP (or substrate). In other words, the processing of the SCP (or substrate) described herein may be applied only to its front side, only to its rear side or also to each of the two sides (e.g. one after the other), namely front side and rear side.

Conventionally, the passivation layer is formed by chemical vapor deposition process (CVD process), for example by low-pressure CVD process (LPCVD process), plasma-enhanced CVD process (PECVD process) or normal-pressure CVD process deposition (APCVD process). Various aspects described herein provide a passivation layer formed by PVD process, for example on the rear side of the solar cell (also referred to as photovoltaic cell) and/or on the front side of the solar cell (i.e. the side facing the sun).

With regard to layer-forming processes detailed herein, reference is made to a “sputtering process” as an exemplary PVD process and to ALD as exemplary CVD process.

A chemical vapor deposition process (CVD process) uses one or more gaseous molecules (also referred to as educts or precursors), of which each precursor is decomposed into at least two reaction products, of which at least one reaction product is incorporated into the layer. Optionally, an excess reaction product is removed from the process (e.g., using a pump). Optionally, the CVD process (e.g., PECVD process) may use a plasma, to which the precursor is exposed, e.g., by which the precursor is decomposed. Atomic layer deposition (ALD) is a variant of the CVD process, which uses multiples precursors, to which a coating region is exposed serially. For example, the precursors of the ALD are neither mixed nor supplied simultaneously to the coating region. For example, the precursors of the ALD are supplied by a series of sequential, non-overlapping reaction phases, of which each phase ends with an evacuation process to remove the excess of the reaction (e.g., not consumed precursor and/or reaction products) from the coating region. Each of the precursors may react with the surface in a self-limiting way, so that the reaction terminates once all the available sites on the surface are consumed.

The term “sputtering” refers to the vaporization of a material (also referred to as coating material or target material) by a plasma. The sputtered components of the coating material (e.g. individual atoms and/or ions) are separated from each other and may be deposited elsewhere, for example to form a layer. Sputtering may be carried out using a sputtering device as exemplary processing device, which may include one or more than one magnet system (then also referred to as a magnetron). The coating material may be provided by a sputter target (also referred to as a target), which may, for example, be tube-shaped (also referred to as a tube target or tubular target) or plate-shaped (also referred to as a plate target or planar target). To generate the plasma, a voltage (also referred to as sputter voltage) may be applied to the sputter target (also referred to as target) so that the sputter target is operated as a cathode. Even if the sputter voltage includes an alternating voltage, the term cathode is often retained.

For sputtering, the sputter target may be disposed in a vacuum processing chamber (also referred to simply as a processing chamber) so that the sputtering process may be exposed to a vacuum. For this purpose, the process conditions (the process parameters) within the vacuum processing chamber (e.g. process pressure, temperature, gas composition, etc.) may be adjusted or controlled during sputtering. For example, a working gas may be or be provided within the processing chamber, which denotes the plasma-forming gas or the plasma-forming gas mixture. The processing chamber may, for example, be or become airtight, dust-tight and/or vacuum-tight so that a gas atmosphere with a predefined composition (also referred to as working atmosphere) or a predefined pressure (also referred to as working pressure or process pressure) may be provided within the processing chamber (e.g. according to a setpoint), e.g. a vacuum.

The plasma may be formed by a working gas (also referred to as plasma-forming gas). According to various embodiments, the working gas may comprise a gaseous material which is inert, in other words which participates in few or no chemical reactions. A working gas may be or be defined by and adapted to the target material used. For example, a working gas may be a gas or a gas mixture that does not react with the target material to form a solid or is even inert to it. The working gas may, for example, contain a noble gas (e.g. helium, neon, argon, krypton, xenon, radon) or several noble gases. The plasma may be formed from the working gas, which essentially sputters the target material, for example. If a reactive gas is used, this may have a higher chemical reactivity than the working gas, e.g. with regard to the target material. In other words, the sputtered target material together with the reactive gas (if present) may react faster (i.e. form more reaction product per time) than together with the working gas (e.g. if it chemically reacts with the working gas at all). The reactive gas and the working gas may be supplied together or separately as a process gas (e.g. as a gas mixture), for example by the gas supply device.

It may be understood that what is described herein for sputtering may apply by analogy to any other layer process, e.g. a physical vapor deposition process. In general, physical vapor deposition process (e.g., sputtering) exhibits that the chemical composition of the target or coating material is transferred into the layer to be formed, for example, the sputtered target does not interact (e.g., react) with a reactive gas, which is also referred to as reactive PVD process. When a reactive gas is used, a layer comprising the reaction product of target material and reactive gas may be formed. For example, a SiNx:H layer may be formed using a Si target together with NH3 (ammonia gas) as the reactive gas.

In contrast to CVD process, in PVD process, e.g. sputtering, a solid material is first transferred into the gas phase (also referred to as the gaseous phase or vapor) and a layer is formed using this gas phase. In PVD process, the gas phase of the target material may optionally (e.g. in reactive PVD process) be chemically reacted (also referred to as reactive PVD process or sputtering) with a reactive gas to form a chemical compound, which is incorporated into the layer or forms it. In the chemical reaction of PVD process, two or more materials are thus brought together to form the chemical compound.

Sputtering is used, for example, to form a semi-crystalline to amorphous silicon thin film, which is subsequently treated in a high-temperature step for doping and/or crystallization (known as solid phase crystallization).

For simplified understanding, reference is made herein to n-doping as exemplary doping of the first type (e.g. n-type or donor type) and p-doping as exemplary doping of the second type (e.g. p-type or acceptor type). For example, the physical structure of a solar cell (e.g. in TOPCon technology) is explained using an n-doped core sublayer (e.g. provided by a silicon wafer) with a p-doped emitter sublayer (e.g. doped using boron). It may generally be understood that what is described for these exemplary dopants may apply by analogy to an opposite doping.

In general, the passivated contact (e.g. TOPCon) may include stack of multiple layers comprising a doped semiconductor layer (e.g., a transfer layer). The transfer layer matches the core sublayer in its doping type (e.g. n-type or p-type) and differs from the emitter sublayer in its doping type. In an exemplary implementation, the solar cell includes the p-type doped emitter sublayer on the side facing the sun, the front side of the solar cell, and an n-type doped passivated contact on the side facing away from the sun, the rear side of the solar cell. The described may therefore also apply to a solar cell with a p-doped core sublayer (e.g., base sublayer) and an n-doped emitter sublayer or a p-doped passivated contact.

Further examples of solar cells in which passivated contacts may be used are solar cells equipped with passivated contacts on both sides (a variant of the heterojunction solar cell), both over the entire surface and locally limited to the use of the rear contact laminate on areas below the metallic contacts, as well as solar cells contacted only on the rear side facing away from the sun, in which both types of charge carriers (electrons and holes) are discharged to the outside via electrical contacts on one side of the solar cell.

It also refers to a metallization (e.g. back-surface metallization or front-surface metallization), for example as part of the passivated contact. This metallization may, but does not necessarily have to, also be formed after the SCP includes been transported out of the processing region, for example after it includes been ejected from the vacuum arrangement (e.g. the vacuum provided therein). This metallization may, for example, be formed by screen printing or another printing process, such as inkjet, rotary or extrusion printing, or by electroplating.

With regard to the passivated contact, reference is made herein by way of example to the tunnel oxide passivated contact (TOPCon). What is described herein by way of example for the TOPCon may apply by analogy to any other type of passivated contact which, for example, does not necessarily have to have a tunnel oxide, but may instead have another oxide or a nitride.

The Fill Factor (FF) is a representative parameter that measures the quality of a solar cell's output. It is defined as the ratio of the maximum power output of the solar cell (Pm) to the product of the open-circuit voltage (Voc) and the short-circuit current (Isc). The Pseudo Fill Factor (pFF) is a related parameter that is used to assess the potential fill factor of a solar cell without the influence of series resistance. The term “Eta” (n) refers to the efficiency of the solar cell.

The term “passivation”, e.g., in context to an object, such as a layer (e.g., capping, coating, etc.) or material (also referred to as passivation material) indicates passivating properties, e.g., providing chemical, crystallographic and/or electrical passivation (e.g., neutralizing defects, being dielectric and/or being inert). For example, the object may include or consist of a ceramic (e.g., an oxide, nitride and/or carbide, or mixtures thereof).

In the following, reference is made to the layer stack, a method for forming the layer stack and a respective process system, wherein the references made in this context may in analogy apply to a layer stack, which is not necessarily integrated in a solar cell, e.g., providing another type of electronic device.

In context of a photovoltaic device (e.g., a solar cell), the terms “front” or “front side” refer to the side (also referred to as exposure side), which is configured to face the sun, wherein the terms “rear” or “rear side” refer to the side opposite thereto.

The term “outgassing” is understood a depletion of gas from an object, e.g., from a layer or material. The gas may be a hydrogen containing gas, such as, for example, molecular hydrogen and/or water containing gas (e.g., moisture).

The term “carrier layer” (also referred to as reference layer) may be understood as component, which is processed, e.g., coated by one or more coating processes (e.g., CVD process and/or PVD process). An exemplarily implementation of the carrier layer may include or be formed (e.g., sliced) from a substate (e.g., a wafer) and/or may include one or more doped sublayer. Alternatively or additionally, the carrier layer may be coated, e.g., by one or more layers, of which examples include: a rear carrier passivation (e.g., tunnel dielectric layer), a front protection layer (providing a protected front side of the carrier layer); and/or a rear protection layer (providing a protected rear side of the carrier layer).

The term “purity” in context to a material refers to the molar fraction of the material, e.g., of a material mixture, e.g., an object (such as, e.g., a target or layer) made from the material mixture. The purity quantifies the ratio between the amount of the material (e.g., expressed in unit of moles), and the total amount of all constituents in the mixture (also referred to as material mixture). The purity may be expressed in percentage (e.g., 99.9%) or, as equivalent thereof, as “a.bN”, wherein “a” counts the number “9”, b indicates the number following the last “9”. For example, 3.5N=99.95% or 5N=5.0N=99.999%.

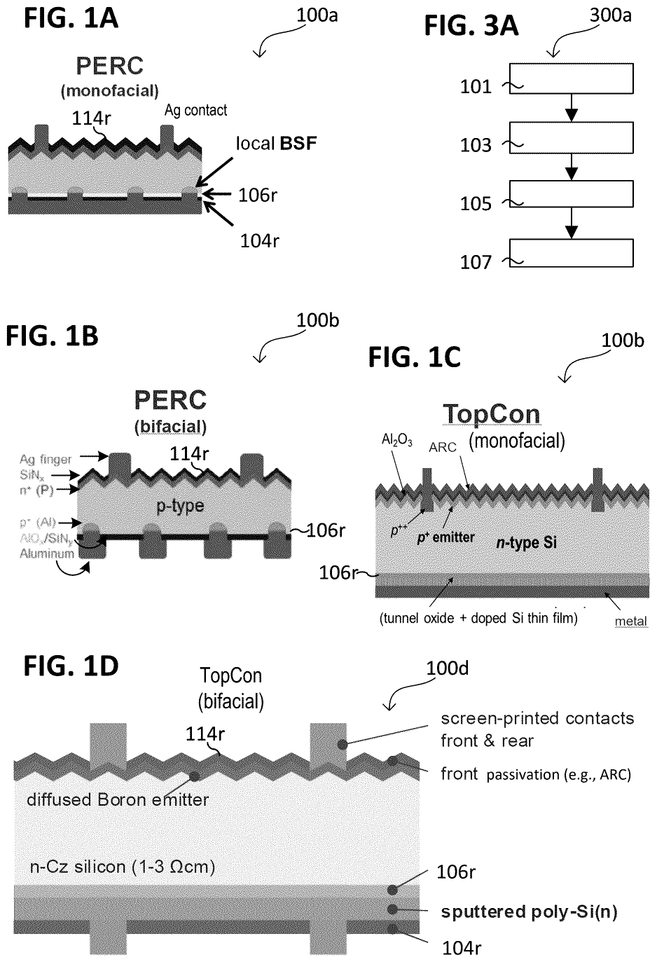

FIG. 1A to FIG. 1D illustrate various architectures for implementing a solar cell according to various embodiments 100a to 100d, in which the layer stack may be integrated, in a schematic cross-sectional diagram. In the context of PERC (Passivated Emitter and Rear Cell) solar cells, “BSF” stands for “Back Surface Field.” The rear surface field denotes a heavily doped layer in the solar cell architectures that enhances the cell's efficiency. In the context of a solar cell, the term “ARC” (Anti-Reflective Coating) denotes an anti-reflective layer (also referred to as ARC). An anti-reflective layer may be applied to one or more sides of a solar cell to reduce the reflection of incoming light, thereby enhancing the generation of electrical energy by the solar cell. The tunnel oxide (also referred to as TO) layer denotes a thin dielectric layer (e.g., having a thickness of less than 10 nm, e.g., less than 5 nm) and may be consist of silicon dioxide (SiO₂).

As example, the TO layer may be formed by a thermal oxidation process, to which the core sublayer is exposed, thereby transferring a semiconducting material (e.g., Si) of the core sublayer to an oxide thereof, which forms the TO layer. In another example, the TO layer may be formed by PVD process, for example, by sputtering.

Variants, as illustrated, include monofacial and bifacial architectures. Further variants of the TOPCon solar cell (also referred to as tunnel oxide passivated contact based solar cell) are detailed in the following. It may be understood that the references made to a TOPCon solar cell may apply in analogy to the layer stack and/or any architecture for a solar cell including the layer stack, not necessary limited to PERC or one of monofacial and bifacial architectures.

Exemplarily components of the carrier layer include: semiconductor material (e.g., silicon), a semiconductor junction, multiple sublayers (e.g., providing the semiconductor junction), one or more dopants (e.g., boron, phosphorous, etc.). Examples of the multiple sublayers include: an emitter sublayer (also referred to as emitter or emitter layer) and a core sublayer (also referred to as core or core layer). The emitter sublayer and the core sublayer may include a dopant (also referred to as being doped), e.g., differing from each other in the type of doping.

Examples of (dielectric and/or passivation) layers include: a rear carrier passivation 106r (also referred to as RB passivation or rear carrier passivation layer), rear stack passivation 114r (also referred to as rear stack passivation layer or rear capping layer), a front stack passivation 114v (also referred to as front stack passivation layer or front capping layer), a front carrier passivation 106v (also referred to as FB passivation or front carrier passivation layer). As example, the rear stack passivation 114r may include or be consist of silicon nitride (e.g., SiNx), e.g., hydrogenated nitride (e.g., SiNx:H). Alternatively or additionally, the rear carrier passivation 106r may include or be consist of silicon oxide (e.g., SiOx). For a bifacial architecture, the rear stack passivation 114r may be configured as rear ARC. In TOPCon technology, the rear carrier passivation 106r may be configured as tunnel oxide layer. The front stack passivation 114v (e.g., including or consist of SiNx, e.g., SiNx:H) may be configured as front anti-reflective layer (also referred to as front ARC).

According to various aspects, the layer stack may include one or more protection layer, preferably when a passivation layer of the layer stack is formed by PVD process (also referred to as PVD process formed passivation layer). For example, the layer stack may include at least one protection layer per PVD process formed passivation layer, on which the PVD process formed passivation layer is formed. Examples of the one or more protection layer may include: the rear carrier passivation 106r being configured as protection layer (e.g., including or consist of Al₂O₃), e.g., in PERC technology, and/or the front carrier passivation 106v being configured as protection layer (e.g., including or consist of Al₂O₃). Alternatively or additionally, one or more further protection layer may be used, which are not illustrated.

FIG. 2A illustrates a solar cell according to various embodiments 200a in a schematic cross-sectional diagram. The architecture shown here relates to the finished solar cell, which (for example together with one or more than one additional solar cell) may be further processed to form a module (also referred to as a solar cell module or solar module) by electrically connecting its metallizations 110, 112 to a connection terminal and/or an additional solar cell. The SCP descriptively refers to the precursor of the solar cell, which may already have some, but not necessarily all, of the components of the solar cell, as explained below.

The SCP includes a doped (e.g., n-doped) first semiconductor layer as core sublayer 102, e.g., a provided by a wafer, which is disposed between a front surface 100v and a rear surface 100r of the SCP. The front side 100v of the SCP may optionally be textured (also referred to as texturing), e.g., structured. This improves the light absorption.

The SCP further comprises a doped (e.g. p-doped) second semiconductor layer as emitter sublayer 104, e.g., adjacent to the core sublayer 102 and/or facing the front side 100v. The core sublayer 102 and the emitter sublayer 104 may form a (for example bipolar) semiconductor junction (then also referred to as pn-junction), for example if they differ from each other in their doping type (e.g. n-type or p-type).

The SCP also includes one or more than one dielectric layer, e.g., providing one or more passivation layers and/or one or more protection layers, which consist of a dielectric material (e.g., a passivation dielectric). Examples of the one or more than one passivation layer comprise: a first passivation layer 106v (also referred to as front carrier passivation 106v) on the front side 100v (then also referred to as passivated front side 100v) and/or a second passivation layer 106r (also referred to as rear side passivation 106r or as RB passivation 106r) on the rear side 100r (then also referred to as passivated rear side 100r).

The core sublayer 102 is disposed between the RB passivation 106r, if present, and the emitter sublayer 104. The RB passivation 106r may, for example, be formed as a tunnel oxide layer. Then, for example, the RB passivation 106r may have a thickness of less than about 5 nanometers (nm), e.g., less than about 2 nanometers (nm) and/or in a range of about 1 nm to about 2 nm.

The dielectric material may include, for example, a semiconductor material (e.g., silicon), e.g., in a chemical compound and/or the semiconductor material of the core sublayer 102. Examples of the one or more than one dielectric material include: a chemical compound of a semiconductor material and oxygen, a chemical compound of a semiconductor material and carbon, a chemical compound of a semiconductor material and nitrogen, an oxide, a carbide, a nitride, or mixtures thereof. For example, the RB passivation 106r includes or consists of a semiconductor oxide (e.g. silicon oxide).

The processing of the SCP as described herein may comprise processing a passivated side (e.g., rear side 100r and/or front side 100v) of the SCP, e.g., by coating with a (e.g., amorphous and/or doped) layer (also referred to as a transfer layer) that contacts (e.g., electrically and/or physically) the passivation layer or passivated side. The processing of the passivated side (e.g. rear side 100r and/or front side 100v) of the SCP may include a physical vapor deposition process (PVD process), as will be explained in more detail later.

With reference to the solar cell illustrated herein, the processing of the SCP may comprise processing the passivated rear side 100r, e.g., by coating with an (e.g., amorphous and/or doped, e.g., n-doped) transfer layer 108r (then also referred to as rear transfer layer 108r), which contacts (e.g., electrically and/or physically) the RB passivation 106r.

Processing the SCP may include one or more metallizing processes, which may or may not necessarily be performed in a vacuum. As example, the metallizing processes may include forming a rear metallization 112 (also referred to as rear contact 112) by coating the rear transfer layer 108r with an electrically conductive (e.g., comprising a metal or at least metallic) material that contacts (electrically and/or physically) the rear transfer layer 108r.

The rear side of the carrier layer (e.g., the core sublayer 102) is coated by multiple layers (also referred to as a rear contact laminate) including one or more of: the rear metallization 112, the rear stack passivation 114r formed thereunder (for example a light coupling layer, as will be described in more detail later), the transfer layer 108r formed thereunder, and/or the RB passivation 106r formed thereunder. The rear contact laminate may implement the passivated contact, e.g., provided by a tunnel oxide layer as rear transfer layer 108r, which may be then referred to as a rear tunnel oxide passivated contact (TOPCon “Tunnel Oxide Passivated Contact”). The rear TOPCon illustrated here may be configured as an n-type TOPCon (n-TOPCon). In some stages of processing the SCP, the passivated contact may be without metallization and/or without anti-reflective layer (e.g., a light coupling layer). What is described herein with reference to TOPCon may apply in analogy to any other implementations of a passivated contact, which does not necessarily include a tunnel oxide, for example.

An exemplarily implementation of the rear contact (e.g. the metallization, e.g. the metallic contacting) formed on a single-sided TOPCon, for example on the rear side 100r, may be grid-shaped and/or realized by a grid (as with a double-sided TOPCon). Alternatively or additionally, at least the RB passivation and/or the transfer layer (e.g. including or formed from aSi and/or polySi) and/or the light coupling layer may also be formed over the entire surface of the rear side. Alternatively or additionally, the transfer layer (e.g. the aSi/polySi layer) of the TOPCon may only be formed below the grid-shaped metallization, for example if the TOPCon is disposed on the front side 100v of the SCP (or the finished solar cell) is only to be contacted on one side.

In an exemplary implementation, the transfer layer of the TOPCon consisting of aSi (e.g. n-doped) and/or polySi (e.g. n-doped) may be or be formed as a grid. For example, the transfer layer may be or be formed only under the grid-shaped metal contacts of the solar cell and/or includes multiple through openings (also referred to as via openings).

The SCP optionally includes an (for example dielectric and/or transparent) ARC 114v on the front side 100v (also referred to as front-side ARC 114v), which includes one or more than one anti-reflective sublayer (for example a stack of several anti-reflective layers).

The thickness of the front-side ARC 114v may be, for example, in a range from about 50 nm to about 500 nm. For example, the front-side ARC 114v may have a refractive index of less than about 2.2, e.g., less than about 1.5, e.g., less than about 1.4. For example, the front-side ARC 114v may be dielectric, e.g., including or formed from a nitride (e.g., a semiconductor nitride, e.g., silicon nitride). For example, the ARC 114v comprises or consists of silicon nitride.

The SCP (e.g., the rear contact laminate thereof) optionally comprises an ARC 114r (e.g., dielectric and/or transparent) on the rear side 100r (also referred to as the rear ARC 114r), which comprises one or more than one anti-reflective sublayer (e.g., a stack of multiple anti-reflective layers). The thickness of the rear ARC 114r may be, for example, in a range from about 50 nm to about 500 nm. The rear ARC 114r may, for example, have a refractive index of less than about 2.2, e.g., less than about 1.5, e.g., less than about 1.4. The rear ARC 114r may, for example, be disposed between the rear metallization 112 (if present) and the RB passivation 106r (if present), e.g., in physical contact with the transfer layer 108r, and/or the rear metallization 112 (if present). If the rear ARC 114r is present and dielectric, the stack of RB passivation 106r, transfer layer 108r (if present), and rear ARC 114r may also provide, for example, a rear passivation or provide at least a portion of a rear TOPCon layer stack.

An exemplarily implementation of the rear ARC 114r is dielectric, e.g., including or consist of a nitride (e.g., a semiconductor nitride, e.g., silicon nitride). For example, the ARC 114r comprises or consists of silicon nitride. Optionally, the rear ARC 114r may comprise hydrogen. This achieves that hydrogen may be provided from the rear ARC 114r, which improves the passivation properties of the TOPCon by reducing the recombination of free charge carriers at the interface, e.g. by saturating free bonds at the interface of substrate 102 and tunnel oxide 106r. For example, the rear ARC 114r may include or consist of hydrogenated nitride (e.g., SiNx:H).

Optionally, the front-side ARC 114v, if present, may have one or more than one via opening, each via opening of which exposes a highly doped portion 104l of the emitter sublayer 104 (also referred to as the local emitter 104l). Alternatively or additionally, the or each through-hole of the front-side ARC 114v may be filled with an electrically conductive (e.g., comprising a metal or at least metallic) material that contacts (electrically and/or physically) the emitter sublayer 104. The electrically conductive material may be part of a front side metallization 110 (also referred to as front side metallization 110) and/or at least protrude from the ARC 114v.

An exemplarily implementation of the emitter sublayer 104 is disposed between the core sublayer 102 and the front side metallization 110, if present, and/or the front ARC 114v, if present.

FIG. 2B illustrates a solar cell according to various embodiments 200b in a schematic cross-sectional architecture diagram, which is similar to embodiments 200a, with the difference that (alternatively or in addition to the rear side 100r) the front side 100v is passivated (by the front carrier passivation 106v) or a TOPCon (or at least a part thereof) is or will be formed thereon. The emitter sublayer 104 is disposed between the front carrier passivation 106v and the core sublayer 102.

Processing the SCP (e.g., the passivated rear side 100r) may include forming an amorphous and/or doped (e.g., p-doped) transfer layer 108v on the front carrier passivation 106v (then also referred to as the front side transfer layer 108v), which contacts (e.g., electrically and/or physically) the front carrier passivation 106v. An exemplarily implementation of the front-side passivation 106v is configured as a tunnel oxide layer and/or may have a thickness of less than about 5 nanometers (nm), e.g., less than about 2 nanometers (nm) and/or in a range of about 1 nm to about 2 nm.

Processing the SCP my further include coating the front-side transfer layer 108v with the front-side ARC 114v and/or an electrically conductive (e.g., comprising a metal or at least metallic) material that contacts (electrically and/or physically) the front-side transfer layer 108v and/or the front-side ARC 114v. The electrically conductive material may form the front side metallization 110. The front-side transfer layer 108v may be disposed between the emitter sublayer 104 and the front-side ARC 114v, if present, and/or the front-side metallization 110, if present.

Optionally, the front-side ARC 114v may include one or more than one via opening, each via opening of which exposes a portion of the front-side transfer layer 108v.

Alternatively or additionally, the or each through opening of the front-side ARC 114v may be filled with the electrically conductive (e.g., comprising a metal or at least metallic) material of the front-side metallization 110, which contacts (electrically and/or physically) the emitter sublayer 104, for example.

The coated front side 100v includes a front contact laminate including one or more of: the front side metallization 110, the ARC 114v formed thereunder, the transfer layer 108v formed thereunder, and the front carrier passivation 106v formed thereunder. The front contact laminate may implement a front tunnel oxide passivated contact (TOPCon), e.g., provided by a tunnel oxide layer as front side transfer layer 108v. The front TOPCon illustrated here may be configured as a p-type passivated front-side contact.

An exemplarily implementation of the rear transfer layer 108r, if present, is coated with an (for example dielectric) ARC 114r on the rear side 100r (also referred to as rear-side ARC 114r). Alternatively or additionally, the rear transfer layer 108r, if present, may be coated with an electrically conductive (e.g., comprising a metal or at least metallic) material that contacts (electrically and/or physically) the transfer layer 108r and/or the ARC 114r. The electrically conductive material may form or at least be part of the rear metallization 112.

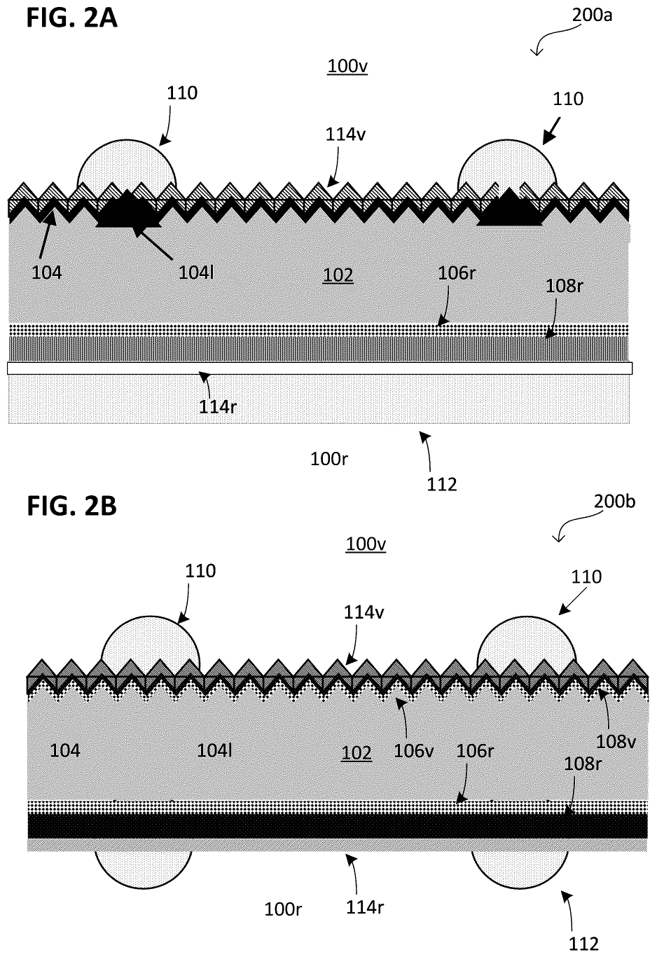

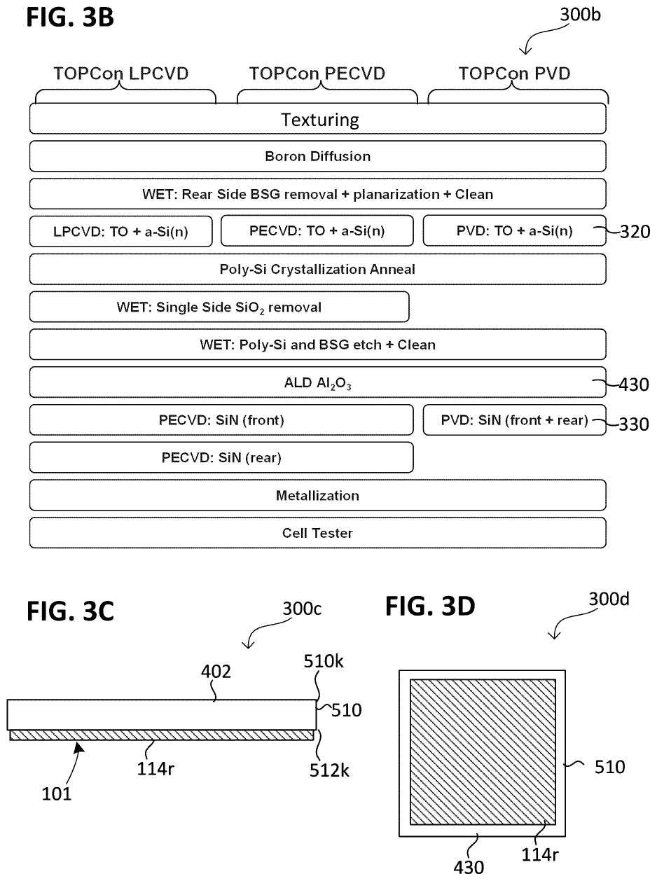

FIG. 3A illustrates a method according to various embodiments 300a in a schematic flowchart. The method comprises, in 303, sputtering a sputter target into a processing region (in which, for example, a vacuum is formed); and in 305, disposing a device precursor (e.g., the SCP) in the processing region, e.g., with a protected and/or passivated side of the device precursor facing the sputter target. The method optionally comprises, in 301, transporting the device precursor into the vacuum formed in the processing region; and in 307, transporting the device precursor out of the vacuum formed in the processing region. For example, when the device precursor is disposed in the processing region and/or when the sputter target is sputtered into the processing region, the device precursor may be disposed in a substrate carrier (e.g., a carrier frame thereof), e.g., in a recess (also referred to as a substrate receiving pocket) thereof, as will be discussed in more detail later.

An exemplarily implementation of the device precursor may, when being transported (e.g., transferred from terrestrial atmosphere) into the vacuum, include: the carrier layer and one or more of: a metal oxide containing first protection layer formed over a front side of the carrier layer by CVD (e.g., ALD or PECVD), and/or a metal oxide containing second protection layer formed over a rear side of the carrier layer by CVD (e.g., ALD or PECVD). In this implementation, the method may include exposing the first and/or second protection layer (which provide a protected side of the precursor) to the outgassing process, e.g., by exposing the protection layer to a plasma formed in the vacuum.

For example, the substrate, when being disposed in the processing region and/or when the sputter target is sputtered into the processing region, may be at a temperature (also referred to as a coating temperature) of less than about 400° C., preferably less than about 300° C., and/or less than a temperature of the sputter target. This favors better layer properties, saves energy, inhibits the formation of toxic volatiles.

For example, the sputter target may comprise a semiconductor material (e.g., that of the core sublayer 102 and/or that of the RB passivation 106r) and/or may be is exposed to a hydrogen containing atmosphere. To protect the carrier layer (e.g., the core sublayer 102 thereof) from the impact of the sputtering process, various embodiments utilize a protection layer formed by ALD (atomic layer deposition) or another CVD process-process (e.g., PECVD), which is exposed to the sputtering process and/or faces the sputter target. The protection layer may include or be formed from a metal oxide, e.g., Aluminum oxide.

An exemplarily implementation of a protection layer may be provided by or formed on (e.g., in contact with) the front carrier passivation 106v (if present) or the rear side passivation 106r (if present). For example, the protection layer may be formed by CVD process, e.g., by a plasma-assisted CVD process in vacuum (PECVD process) or atomic layer deposition (ALD). Alternatively or additionally, the rear side passivation 106r (e.g. comprising a tunnel oxide layer and/or silicon oxide) may be formed by a wet chemical process, by a plasma-assisted process in vacuum (e.g. PECVD process, LPCVD process, PVD process, ALD, etc.), and/or by thermal reaction (e.g. oxidation). The thermal reaction may involve exposing the side of the substrate to a reactive gas (e.g. oxygen or ozone) when this is brought to or above a temperature (also referred to as the reaction temperature), at which substrate reacts with the reactive gas (e.g. above 300° C.). The thermal reaction may, for example, be conducted in a tube furnace.

Forming one or more passivation layer by PVD process allows avoiding usage of a toxic gas, to which the substrate is exposed. Examples of toxic gases include SiH₄ and/or PH₃. For example, using sputtering for forming the one or more passivation layers (compared to CVD process) allows for a lower coating temperature and/or less hydrogen to which the substrate is exposed. The reduction of hydrogen helps to avoid blistering, which induces a flaking of the passivation layers due to the formation of gas bubbles (e.g. hydrogen bubbles). Alternatively or additionally, a outgassing (e.g., moisture and/or hydrogen depletion) process may be applied, e.g., by heating of the substrate to high temperatures above 300° C., e.g. to approx. 350 C or >400 C, is beneficial to reduce the risk of blistering, which is technically established.

FIG. 3B illustrates a method for manufacturing a TOPCon solar cell according to various embodiments 300b (also referred to as TOPCon PVD process) in a schematic diagram, in comparison to conventional CVD process-based methods, including plasma enhanced CVD process (PECVD process) and low pressure CVD process (LPCVD process). As apparent, in contrast to the CVD process-based methods, one or more (e.g., each) layer of the tunnel oxide passivated contact 320 may be formed by PVD process (e.g., a sputtering process), for example, the TO layer as RB passivation 106r and/or an amorphous silicon (a-Si) layer as transfer layer 108r. Alternatively or additionally, one or more passivation layers 330 may be formed by PVD process (e.g., a sputtering process) and/or from a nitride (e.g., silicon nitride).

The term “WET” refers to a wet chemical process, e.g., including an etching process (also referred to as “etch”). The term “Anneal” refers to a thermal annealing process, e.g., including heating the SCP. The term “Poly-Si” refers to polycrystalline silicon. The term “BSG” (Boron-Doped Silicon Glass) represents a dopant source (e.g., poly-silicon) layer from which the dopant is transferred into the carrier layer to form the emitter sublayer on the core sublayer. In this example, boron is used as dopant.

The one or more passivation layers 330 may include a first passivation layer (also referred to as front passivation layer) on a front side of the carrier layer, e.g., providing the front ARC 114v and/or consisting of silicon nitride (SiN). Alternatively or additionally, the one or more passivation layers 330 may include a second passivation layer (also referred to as rear passivation layer) on a rear side of the carrier layer, e.g., consisting of silicon nitride (SiN) and/or providing the rear ARC 114r.

As depicted, prior to forming the one or more passivation layers 330, the SCP is protected by one or more protection layer 430, which may be formed by ALD and/or from aluminum oxide (e.g., Al₂O₃). The one or more protection layer 430 may include a first protection layer (also referred to as front protection layer), e.g., disposed between the front passivation layer and the carrier layer and/or being in physical contact with the front passivation layer. Alternatively or additionally, the one or more protection layer 430 may include a second protection layer (also referred to as rear protection layer), e.g., disposed between the rear passivation layer and the carrier layer and/or being in physical contact with the rear passivation layer

FIG. 3C illustrates a SCP according to various embodiments 300c in a schematic cross-sectional view; and FIG. 3D illustrates the SCP according to various embodiments in a schematic view 300d onto the rear ARC 114r as exemplarily rear passivation layer.

According to various aspects, the SCP is disposed in a carrier frame, when forming the rear passivation layer, which covers a perimeter of the SCP. As consequence, the carrier frame avoids that a circumferential stripe (also referred to as line-shaped region) of the SCP (e.g., rear protection layer 430) is coated by the ARC 114r.

As shown, the ARC 114r may be distant from the sidewall 510 of the SCP, for example, by more than about 0.5 mm (millimeters), e.g., more than about 1 mm (e.g., more than about 2 mm, e.g., more than about 3 mm), and/or less than 10 mm (e.g., less than 5 mm). This circumferential stripe may, for example, cause a color variation towards the sidewall 510 of the solar cell precursor (SCP), indicating that the ARC 114r is formed by PVD process, e.g., by a sputtering process. The sidewall 510 of the SCP may delimit the carrier layer 402 of the SCP and may be delimited by tow circumferential edges 510k, 512k of the SCP.

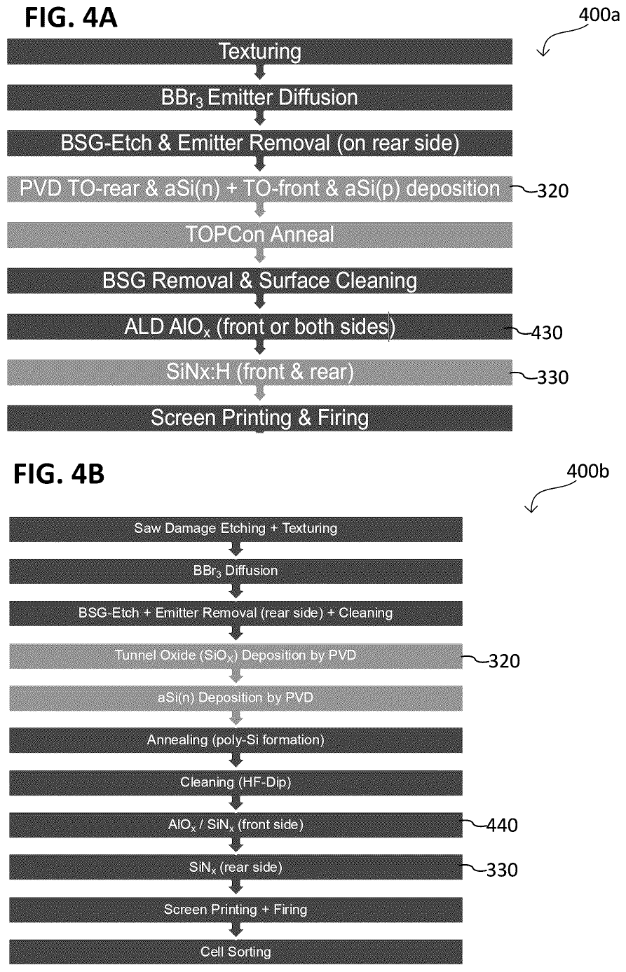

FIG. 4A illustrates a method for manufacturing a TOPCon solar cell according to various embodiments 400a in a schematic diagram, similar to the embodiments 300b. Here, the dopant source layer includes boron (B) as dopant and bromine (Br), e.g., a chemical compound thereof (e.g., boron tribromide).

An exemplarily implementation of the method may include forming one or more TO layers as exemplarily dielectric layer by PVD process, e.g., by a sputtering process. The one or more TO layers may include a first TO layer (also referred to as TO-front) on the front side of the carrier layer. Alternatively or additionally, the one or more TO layers may include a second TO layer (also referred to as TO-rear) on the rear side of the carrier layer.

An exemplarily implementation of the method may include forming one or more doped a-Si (aSi) layer by PVD process, e.g., by a sputtering process. The one or more a-Si layers may include a p-doped a-Si layer (also referred to as aSi(p)) on the front side of the carrier layer. Alternatively or additionally, the one or more a-Si layers may include a n-doped a-Si layer (also referred to as aSi(n)) on the rear side of the carrier layer.

An exemplarily implementation of the method may include forming one or more hydrogen containing silicon nitride layer (as exemplary passivation layer 330) by PVD process, e.g., by a sputtering process, which is exposed to hydrogen, e.g., to a hydrogen containing gas. The one or more silicon nitride layer may, for example, include substoichiometric silicon nitride (SiNx) and/or may be formed in a hydrogen containing atmosphere, e.g., including (e.g., molecular) nitrogen. For example, the hydrogen containing atmosphere may include the hydrogen containing gas, of which examples include: ammonia and molecular hydrogen.

The one or more silicon nitride layer may include a first silicon nitride layer (also referred to front silicon nitride layer) on the front side of the carrier layer, e.g., providing a front ARC 114v. Alternatively or additionally, the one or more silicon nitride layer may include a second silicon nitride layer (also referred to rear silicon nitride layer) on the rear side of the carrier layer, e.g., providing a rear ARC 114r.

An exemplarily implementation of the one or more hydrogen containing silicon nitride layer may be exposed to the metallizing processes, which includes forming a metallization on the or each silicon nitride layer (e.g., by screen printing) and exposing the metallization to a thermal annealing process (also referred to as firing or firing process).

According to various embodiments, prior to forming the one or more hydrogen containing silicon nitride layer, the SCP is protected by one or more protection layer 430, which may be formed by ALD and/or from substoichiometric aluminum oxide (e.g., AlOₓ). The one or more protection layer 430 may include a front protection layer disposed between the front silicon nitride and the carrier layer. Alternatively or additionally, the one or more protection layer 430 may include a rear protection layer disposed between the rear silicon nitride layer and the carrier layer.

FIG. 4B illustrates a method for manufacturing a TOPCon solar cell according to various embodiments 400b (also referred to as TOPCon PVD process) in a schematic diagram similar to embodiments 400a. Among others, embodiments 400b differ from embodiments 400a in bilayer 440 of an AlOₓ layer and a SiNₓ layer, which is only formed on the front side of the carrier layer.

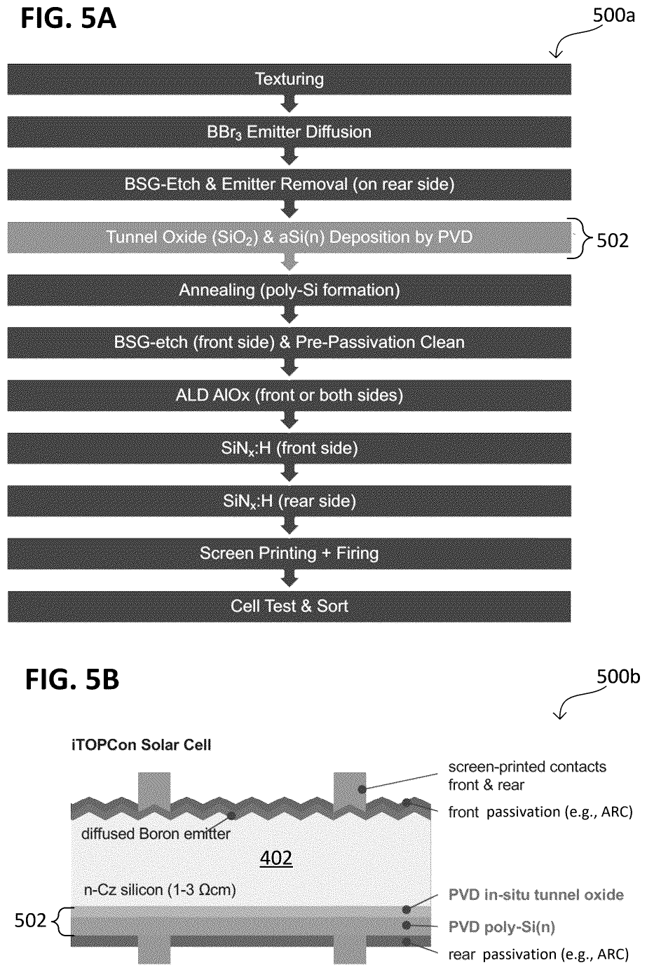

FIG. 5A illustrates a method for manufacturing a i-TOPCon solar cell as variant of the TOPCon solar cell according to various embodiments 500a in a schematic diagram, similar to the embodiments 400a and 400b; and FIG. 5B the i-TOPCon solar cell resulting from the method in a schematic cross-sectional architecture diagram 500b. The term “i-TOPCon” refers to an “industrial Tunnel Oxide Passivated Contact”, denoting methods and architecture optimized for industrial application. As depicted, the method includes forming a stack 502 of a TO layer (e.g., consist of SiO₂) and an a-Si layer on the rear side of the carrier layer 402.

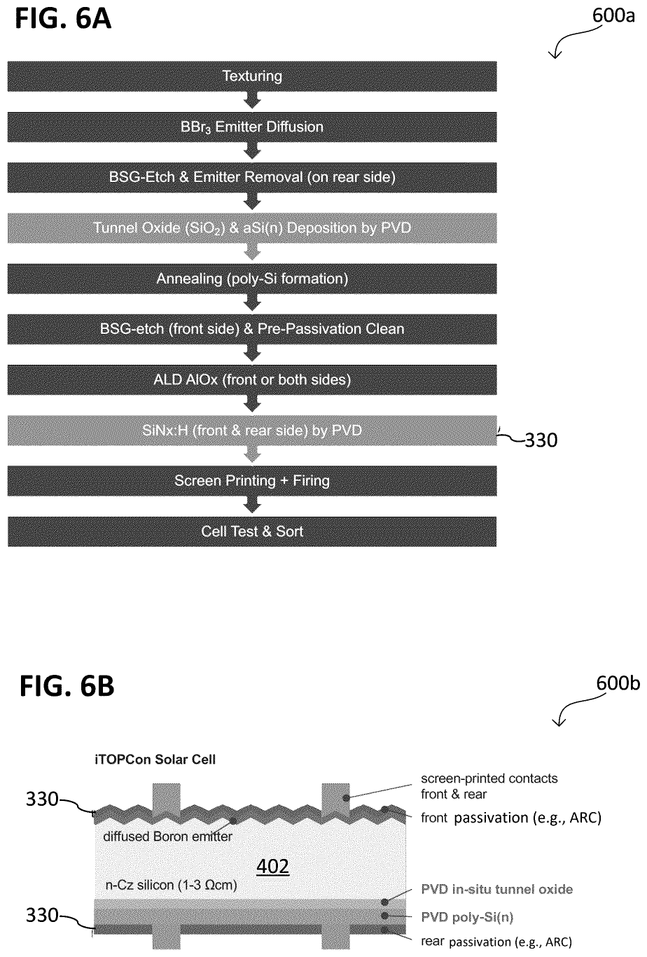

FIG. 6A illustrates a method for manufacturing a i-TOPCon solar cell as variant of the TOPCon solar cell according to various embodiments 600a in a schematic diagram, similar to the embodiments 400a and 400b; and FIG. 6B the i-TOPCon solar cell resulting from the method in a schematic cross-sectional architecture diagram 600b. As depicted, the method includes forming a two passivation layers 330 by PVD process (e.g., a sputtering process), between which the carrier layer 402 is disposed. Further, a one or more protection layer 430 may be formed between the two passivation layers 330, of which a rear protection layer 430 may be disposed between the tunnel oxide layer and the rear passivation layer; and/or of which a front protection layer 430 may be disposed between the emitter sublayer and the front passivation layer.

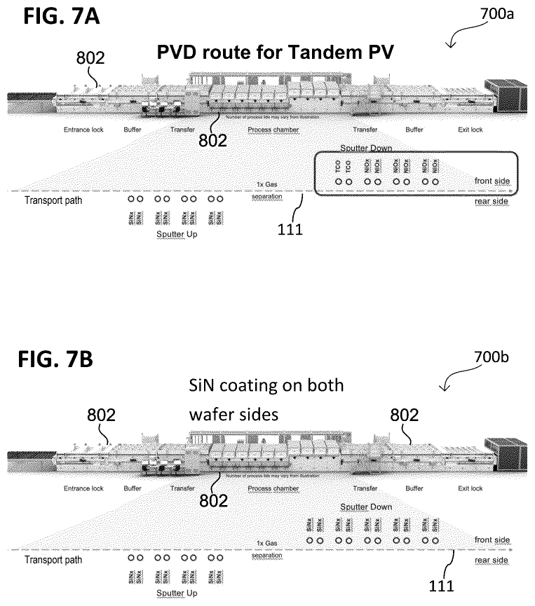

FIG. 7A and FIG. 7B illustrate each a process system for forming the layer stack according to various embodiments 700a, 700b in various diagrams, including a schematic perspective view (top) and a process diagram (bottom).

The process system comprises a plurality of vacuum chambers 802 disposed in a row along a transport path provided by a transport device. The plurality of vacuum chambers 802 include one or more than one vacuum chamber, in which one or more process devices are disposed (then also referred to as process chambers), by which the layer stack is formed. The one or more process chambers are configured in accordance with a process sequence resulting in the layer stack and/or implementing the method detailed herein.

An exemplarily implementation of each of the process devices is provided as magnetron including one or more tubular targets (represented by circles), which are sputtered by a plasma during the PVD process. The targets may consist of Si or SiN. The plasma may be supplied by ammonia, molecular hydrogen and/or (e.g., molecular) nitrogen. Multiple first process devices may be disposed below the transport path 111 (also referred to as sputter up configuration) for forming a SiNx layer on the rear side of the carrier layer. Multiple second process devices may be disposed above the transport path 111 (also referred to as sputter down configuration) for forming a SiNx layer on the front side of the carrier layer.

In the following, various working examples are provided with reference to the aspects described herein.

According a working example 1, a sputtering process is used for producing one or more (e.g., hydrogen containing) silicon nitride layer (e.g., SiNx:H) as passivation layer. A thickness of the or each silicon nitride layer may be in the range between 60 nm (nanometer) and 120 nm, preferably between 70 nm and 75 nm. Alternatively or additionally, a refractive index of the or each silicon nitride layer may be in the range between 1.8 and 2.2, preferably between 2.0 and 2.05. These properties facilitate the usage of the silicon nitride layer as an anti-reflection layer.

According a working example 2, which may be configured in accordance with example 1, a sputtering process is used for producing one or more hydrogen containing passivation layer, e.g., silicon nitride layer. The hydrogen content of the passivation layer facilitates the usage of the passivation layer as hydrogen source (also referred to as H-source), e.g., for interface passivation in a crystalline silicon solar cell.

According a working example 3, which may be configured in accordance with one of examples 1 to 2, a solar cell may be formed in accordance with PERC technology or TOPCon technology. Both technologies provide one or more hydrogen containing silicon nitride layer (e.g., SINx:H) layers used as an anti-reflex layer, as H-source and/or as a surface passivation layer (e.g., in PERC technologies).

According a working example 4, which may be configured in accordance with one of examples 1 to 3, PVD process provides various advantages over CVD process (e.g., PECVD process), which may be attractive for industrial implementation, even if considered that CVD process is established, provides good efficiency with sufficiently high optical quality and homogeneity. Examples of the advantages of PVD process over CVD process may include:
Less or avoidance of toxic gases, which are necessary for PECVD process to form a SiNx: H layer, such as SiH₄ (silane) and/or NH₃ (ammonia),
Less or avoidance of expensive and/or unavailable gases (e.g., silane and/or ammonia), which are not equally available over the world. For example, silane requires high safety precautions during transportation and installation and therefore entails high building, installation and follow-up costs in terms of safety monitoring and environmentally friendly disposal.
   Other examples of the advantages of PVD process over CVD process may include:
PVD process provides better homogeneity (e.g., +−2%), which reduces recombination losses, which are reflected in higher pseudo fill factors pFF and then ultimately higher FF and thus higher efficiency level;
PVD process does not necessarily need an electrical contact (conventionally provided by contact pins) to the substrate (e.g., wafer) during layer formation, which allows to reduce or avoid pin marks, which are several millimeters in size disturbing the layer formation, which are considered as an optical flaw;
PVD process includes a higher compatibility with inline-processing technology and therefore facilitates implementation of the production in accordance with a requirements to High-Volume Manufacturing (HVM);
PVD process works at less temperature of the substrate, thereby reducing the deposition temperature.

According a working example 5, which may be configured in accordance with one of examples 1 to 4, the or each protection layer (e.g., AlOx layer formed by ALD) is exposed to a outgassing (e.g., moisture and/or hydrogen depletion) process, e.g., an outgassing process, thereby reducing the hydrogen content (e.g., provided H or H₂O) of the protection layer, before forming the passivation layer in contact with the protection layer. Reducing the hydrogen content of the protection layer reduces the risk of a blistering process in the passivation layer, e.g., during firing.

According a working example 6, which may be configured in accordance with one of examples 1 to 5, the or each bilayer, formed from a protection layer and a passivation layer contacting the protection layer, facilitates to produce more efficient, optically homogeneous and cost-effective solar cells in an environmentally friendly, cost-effective, tox gas-free manner by sputtering solid-state targets in tubular form.

According a working example 7, which may be configured in accordance with one of examples 1 to 6, a protection layer (e.g., consist of AlOx) may be formed on the front side of the carrier layer by a sputtering process, which provides high homogeneity and thus high pFF and/or FF and/or Eta. The facilitates forming a gradient layer regarding the refractive index with the same hydrogen content in an inline process without the use of a toxic gas.

According a working example 8, which may be configured in accordance with one of examples 1 to 7, a protection layer (e.g., consist of AlOx) may be formed on the rear side of the carrier layer by a sputtering process, and a SiNx:H layer by sputtering thereon. This facilitates a toxic gas-free production process for homogeneous anti-reflection layer, e.g., usable for a bifacial solar cell (higher pFF, FF, Eta) and simultaneously provides a hydrogen source to minimize electrical recombination losses on the rear side of the carrier layer (e.g., for PERC or TOPCon).

According a working example 9, which may be configured in accordance with one of examples 1 to 8, forming one or more passivation layers (e.g., consist of SINx:H) by a sputtering process, e.g., including a rear passivation layer, is facilitated, as the underlying protection layer absorbs the destructive impact of the sputtering process. The rear passivation layer may be configured as anti-reflective layer and as a hydrogen source for the TOPCon contact (e.g., made of a tunnel oxide and aSi).

According a working example 10, which may be configured in accordance with one of examples 1 to 9, forming all rear side layers of a solar cell with the same tool park is facilitated, which saves spare part costs (e.g., in an HVM inline, having lower temperature than PECVD process).

According a working example 11, which may be configured in accordance with one of examples 1 to 10, forming a front side coating of a solar cell, including a SiNx:H layer formed by a sputtering process, may be facilitated by a strong magnetic field, to which the sputtering process is exposed, which increases efficiency and reduces costs, be by using one or more tube magnetrons for the sputtering process.

According a working example 12, which may be configured in accordance with one of examples 1 to 11, the process safety is improved due to the consistent avoidance of toxic gases (PH₃ and SiH₄). NH₃ may also be replaced by a hydrogen containing atmosphere including N₂ and H₂. For example, the hydrogen containing atmosphere may include a content of H₂ in the range from 10% to 20%.

According a working example 13, which may be configured in accordance with one of examples 1 to 12, one or more (e.g., dielectric) protective layers, preferably consist of AlOx, are formed, preferably by ALD, which absorb the destructive impact of the sputtering process, by which a passivation layer (preferably consist of SiN) is formed on each of the one or more dielectric protective layers.

According a working example 14, which may be configured in accordance with one of examples 1 to 13, a outgassing (e.g., moisture and/or hydrogen depletion) process is implemented, to which the one or more (e.g., dielectric) protective layers, are exposed to reduce a hydrogen content (e.g., provided H or moisture) of the one or more protective layers. For example, forming AlOx by ALD often adds hydrogen to the AlOx layer, which may be outgassed by the outgassing (e.g., moisture and/or hydrogen depletion) process. This reduces the risk of blistering of the subsequently formed passivation (e.g., SiN) layer on the protective layer, e.g., during the contact firing process. Illustratively, blistering may be caused by the formation of small gas bubbles that form during the contact firing process, which cause the passivation layer to flake off. By blistering, many small holes (tens of um in size) are formed in the passivation layer, which may impair the performance and reduce Eta.

According a working example 15, which may be configured in accordance with one of examples 1 to 14, a outgassing (e.g., moisture and/or hydrogen depletion) depletion process is implemented by a separate furnace, in which the one or more protective layers are heated to 400°°C. or above (e.g., for about 10 Minutes or more).

According a working example 16, which may be configured in accordance with one of examples 1 to 15, a hydrogen depletion (e.g., outgassing) process is implemented during formation of the passivation (e.g., SiN) layer, by which the one or more protective layers are heated to 400° C. or above (e.g., for about 10 Minutes or more).

According a working example 17, which may be configured in accordance with one of examples 1 to 16, a hydrogen depletion (e.g., outgassing) process is implemented by or prior to the PVD process, by which the passivation layer is formed. As example, a short preheating process in high vacuum may induce hydrogen depletion (e.g., outgassing). As example, the plasma, to which the PVD process, by which the passivation layer is formed, and the protection layer are exposed, contributes sufficiently to hydrogen depletion (e.g., outgassing).

According a working example 18, which may be configured in accordance with one of examples 1 to 17, the protection (e.g., AlOx) layer and/or the passivation (SiN) layer may provide a hydrogen source, by which hydrogen is provided for passivation (also referred to as hydrogen passivation).

According a working example 19, which may be configured in accordance with one of examples 1 to 18, the CVD process, by which the protection (e.g., AlOx) layer is formed, and/or the PVD process, by which the passivation (SiN) layer is formed, may be configured to introduce hydrogen to the respective layer (also referred to as hydrogenation).

According a working example 20, which may be configured in accordance with one of examples 1 to 19, hydrogen provided by one or more hydrogens sources (e.g., the protection layer and/or the passivation layer) may be used for hydrogen passivation, e.g., including neutralizing defects and/or open bonds of the SCP.

According a working example 21, which may be configured in accordance with one of examples 1 to 20, two layer formation processes may be implemented by PVD process, of which each layer formation process is configured to form a passivation (e.g., SiNx:H) layer, and to which the rear side and the front side of the SCP are exposed simultaneously. This saves installation space, automation systems and personnel, reduces scrap due to breakage, which always occurs during handling, and thus lowers costs.

According a working example 22, which may be configured in accordance with one of examples 1 to 21, the two layer formation processes, to which the rear side and the front side of the SCP are exposed preferably simultaneously, may differ from each other in a working point, thereby resulting in passivation (e.g., SiNx:H) layers differing from each other. This saves installation space, automation systems and personnel, reduces scrap due to breakage, which always occurs during handling, and thus lowers costs.

According a working example 23, which may be configured in accordance with one of examples 1 to 22, a line-shaped region of approximately 0.8 mm to 1 mm width is formed along the rim of the SCP, at which the SCP is not coated by the passivation layer (illustratively, at the edge on the rear side of the cell), which is indicative of the PVD process, used for forming the passivation layer.

According a working example 24, which may be configured in accordance with one of examples 1 to 23, the method as detailed herein is compatible with PERC technology, TOPCon technology (e.g., for layer formation of both sides), TOPCon² technology, and TOPCon bottom cell technology, tandem solar cells technology, in particular PVSK-Si tandem solar cells technology.

According a working example 25, which may be configured in accordance with one of examples 1 to 24, the PVD process, by which the or each passivation layer is formed, exposes the carrier layer to a temperatures in the range of 250° C. and 350° C. or less. This lowers the overall temperature budget of the carrier layer (e.g., wafer).

According a working example 26, which may be configured in accordance with one of examples 1 to 25, the PVD process, by which the or each passivation layer is formed, is implemented by an inline process system, which is faster in production than PECVD process and/or requires less equipment per throughput.

According a working example 27, which may be configured in accordance with one of examples 1 to 26, the CVD process, by which the protection layer is formed, is exposed to H₂ and/or N₂ instead of NH₃, which save costs.

According a working example 28, which may be configured in accordance with one of examples 1 to 27, the PVD process, by which a passivation layer is formed, is configured to provide a gradient in the passivation layer, e.g., a gradient of the hydrogen content of the passivation layer and/or a gradient of the refractive index of the passivation layer. For example, the PVD process may be implemented by a time dependent atmospheric composition, to which the PVD process is exposed, and/or multiple process devices differing in their working point. As example, the hydrogen content of the passivation layer may decrease into a direction pointing away from the carrier layer.

According a working example 29, which may be configured in accordance with one of examples 1 to 28, an ARC (e.g., formed by PVD process) may include multiple sublayers, of which a first sublayer is formed from SiOx and a second sublayer is formed from SiN:H. Alternatively or additionally, the may include (e.g., a mix of) multiple (e.g., dielectric) materials, which include a nitride (e.g., SiN:H) and/or an oxide (SiOx).

According a working example 30, which may be configured in accordance with one of examples 1 to 29, a solar cell includes a layer stack, which includes: a thin, e.g. 0.5-3 nm (nanometers) thick, tunnel oxide layer (e.g. made of SiOx), a polycrystalline doped silicon layer formed thereover, a protection layer of Al₂O₃ formed thereover, and a passivation layer of SiNx:H) formed thereover, to improve light coupling and to provide a hydrogen source, and a grid-shaped metallization formed thereover.

According a working example 31, which may be configured in accordance with one of examples 1 to 30, the ALD process was compared to PECVD process for forming the protection layer, which revealed that the ALD process resulted in a better protection layer then the PECVD process, e.g., in terms of layer quality, homogeneity, stoichiometry, and/or transparency.

According a working example 32, which may be configured in accordance with one of examples 1 to 31, a thickness of the PolySi containing transfer layer was 80 nm, a thickness of the AlOx containing rear protection layer was 3-6 nm, and a thickness of the rear passivation layer was 75 nm.

According a working example 33, which may be configured in accordance with one of examples 1 to 32, the solar cell includes: a (n-or p-doped) poly-silicon layer (e.g., 40-200 mm thick, preferably 50-100 nm) on a SiOx tunnel oxide layer (e.g., 0.5-2 nm thick, preferably 1-1.5 nm), an aluminum oxide containing protection layer (e.g., 1-10 nm thick, preferably 3-6 nm) and a hydrogenated silicon nitride (e.g., SiNx:H) containing passivation layer (e.g., 50-120 nm thick, preferably 65-80 nm), e.g., formed on the rear side of a silicon wafer based solar cell (e.g., rear side meaning the side opposite from the sun exposed front side).

According a working example 34, which may be configured in accordance with one of examples 1 to 33, the solar cell includes: a SiNx:H layer as rear passivation layer formed on the rear side of a silicon wafer based solar cell with rear side meaning the side opposite from the sun exposed front side.

According a working example 35, which may be configured in accordance with one of examples 1 to 34, the solar cell includes: an aluminum oxide layer as protection layer (e.g., 1-10 nm thick, preferably 3-6 nm), the hydrogenated silicon nitride (e.g., SiNx:H) containing passivation layer (e.g., 50-120 nm thick, preferably 65-80 nm), e.g., formed on the rear side of a silicon wafer based solar cell (e.g., rear side meaning the side opposite from the sun exposed front side).

According a working example 36, which may be configured in accordance with one of examples 1 to 35, the solar cell includes: an aluminum oxide layer as protection layer (e.g., 1-10 nm thick, preferably 3-6 nm) deposited using an atomic layer deposition (ALD) process and the hydrogenated silicon nitride (e.g., SiNx:H) containing passivation layer (e.g., 50-120 nm thick, preferably 65-80 nm), e.g., formed on the rear side of a silicon wafer based solar cell (e.g., rear side meaning the side opposite from the sun exposed front side).

According a working example 37, which may be configured in accordance with one of examples 1 to 36, the or each protection layer is exposed to an outgassing process, thereby depleting one or more hydrogen containing agents from the protection layer, such as atomic hydrogen, molecular hydrogen and/or a chemical compound including hydrogen, e.g., water (in this context also referred to as moisture). An exemplarily implementation of the outgassing process includes exposing the protection layer to a plasma formed under vacuum (e.g., in a vacuum chamber).

According a working example 38, which may be configured in accordance with one of examples 1 to 37, the or each protection layer is exposed to an outgassing process provided by a plasma, to which (e.g., molecular) nitrogen is supplied.

According a working example 39, which may be configured in accordance with one of examples 1 to 38, a process system, comprising multiple process devices and one or more vacuum chambers, in which the multiple process devices are disposed, is used for forming the layer stack based on a substrate, wherein the substrate provides the carrier layer and is coated with one or more protection layers, which the substrate is transported by a transport device through the one or more vacuum chambers, thereby forming, for each of the one or more protection layers, a passivation layer on protection layer (e.g., in physical contact therewith). Illustratively, the substrate may be coated with one or more protection layers by CVD (e.g., ALD) in another process system (e.g., being spatially separated from the process system), e.g., before entering the process system and/or before being exposed to atmospheric pressure. Optionally, the process system may also provide the outgassing process, e.g., directly after the substrate enters the process system.

According a working example 40, which may be configured in accordance with one of examples 1 to 39, a process system does not necessarily implement all processes of the method. For example, the CVD related processes (e.g., forming the or each protection) may be implemented by another process system, e.g., being spatially separated from the process system.

According a working example 41, which may be configured in accordance with one of examples 1 to 40, a solar cell may include the following layer sequence: wafer (e.g., as carrier layer)—TO layer (e.g., SiOx)—polySi (e.g., as transfer layer)—AlOx layer (e.g., as protection layer)—SiNx: H layer (e.g., as passivation layer, e.g., antireflection layer).

According a working example 42, which may be configured in accordance with one of examples 1 to 41, the method (e.g., of example 2) may include: forming the first passivation layer on (e.g., directly in contact with) a metal oxide containing first protection layer, which is disposed over the carrier layer (e.g., over a front side of the carrier layer) and/or formed by CVD (e.g., ALD or PECVD); and exposing the first protection layer to an outgassing process (e.g., using a plasma and/or annealing process).

According a working example 43, which may be configured in accordance with one of examples 1 to 42, the method (e.g., of example 2) may include: forming the second passivation layer on (e.g., directly in contact with) a metal oxide containing second protection layer, which is disposed over the carrier layer (e.g., over a rear side of the carrier layer) and/or formed by CVD (e.g., ALD or PECVD); and exposing the second protection layer to an outgassing process (e.g., using a plasma and/or annealing process). For example, the carrier layer may be disposed between the first protection layer and the second protection layer.

According a working example 44, which may be configured in accordance with one of examples 1 to 43, various process parameters are adapted to optimize the PVD for forming one or more than one passivation layer. These process parameters are the result of various optimizing procedures, which reveal various critical boundaries, beyond which the production process tends to be of less value and/or results in less efficiency of the solar cell.

According a working example 45, which may be configured in accordance with one of examples 1 to 44, each passivation layer is formed using a dual magnetron sputtering device, which includes two tubular magnetron targets, of which each target includes a molar fraction of silicon in the range of 3.5N to 5N and is doped by a dopant of silicon. Examples to dopant include phosphorus, boron, arsenic, and/or gallium. This provides a passivation layer of high quality at low production costs matching the required properties for a TOPCon solar cell. Illustratively, PVD According a working example 46, which may be configured in accordance with one of examples 1 to 45, stable process conditions are obtain by using the two tubular magnetron targets as electrodes, between which an alternating voltage is applied. This reverses the current flow direction and thereby compensate detrimetral effects. Preferably, the voltage provided between the two tubular magnetron targets has an invariant magnitude, but is periodically inverted (e.g., to provide a square wave alternating voltage). As alternative, a sine square wave alternating voltage or pulsed alternating voltage may be used.

According a working example 47, which may be configured in accordance with one of examples 1 to 46, the kinetic energy, to which the protection layer is exposed, is minimized at reasonable deposition rate for forming the passivation layer, by setting the distance of the solar cell substrate from the two targets, which are used for forming the passivation layer, to a value in the range from 80 mm (millimeter) to 150 mm. This reduces the risk of penetrating through the protection layer, and thereby disturbing the underlying material of the solar cell substrate, without reducing the deposition rate to a value, which is below a threshold for economic production. Further, the electrical power supplied to each target is in the range from 5 kW (Kilowatt) to 15 kW per meter of the target, which provides a suitable trade-of between deposition rate and the risk of penetrating through the protection layer.

According a working example 48, which may be configured in accordance with one of examples 1 to 47, the passivation layer is, while being formed, exposed to a process gas containing a ratio of 10-20% hydrogen and having a pressure in the range from 1 μbar to 3 μbar (1E-3 mbar bis 3E-3 mbar). This provides a suitable chemical composition of the passivation layer for high quality and efficiency.

According a working example 49, which may be configured in accordance with one of examples 1 to 48, the solar cell substrate or at least the protection layer is, while the passivation layer is formed thereon, brought to a temperature in the range of 200° C. to 350° C. This provides suitable layer formation kinetics for high layer quality and efficiency.

Example 50 is configured in accordance with one of examples 1 to 49, wherein a thickness of the passivation layer is 75 nm on the front side of the solar cell and is 105 nm on the rear side of the solar cell. This allows for optimal light conductance and passivation properties.

While the disclosure includes been particularly shown and described with reference to specific aspects, it should be understood by those skilled in the art that various changes in form and detail may be made therein without departing from the spirit and scope of the disclosure as defined by the appended claims. The scope of the disclosure is thus indicated by the appended claims and all changes, which come within the meaning and range of equivalency of the claims, are therefore intended to be embraced.

1. A layer stack comprising:
a carrier layer;
one or more passivation layers formed by a physical vapor deposition process;
wherein the one or more passivation layers comprises a silicon-based passivation layer;
one or more metal oxide containing protection layers comprising, for each passivation layer of the one or more passivation layers, a protection layer formed by a chemical vapor deposition process between the passivation layer and the carrier layer;
a dielectric tunnel oxide layer arranged on a rear side of the carrier layer; wherein a metal oxide containing protection layer of the one or more metal oxide containing protection layers is arranged between the silicon-based passivation layer and the dielectric tunnel oxide layer.

2. The layer stack according to claim 1, wherein the silicon-based passivation layer is in physical contact with the protection layer.

3. The layer stack according to claim 1, wherein each of the one or more passivation layers comprises a nitride of a semiconductor material, wherein the carrier layer comprises the semiconductor material.

4. The layer stack according to claim 3, wherein each of the one or more passivation layers consists of the nitride, and wherein the nitride is hydrogenated.

5. The layer stack according to claim 1, wherein the chemical vapor deposition process is an atomic layer deposition.

6. The layer stack according to claim 1, wherein the metal oxide is aluminum oxide formed by the chemical vapor deposition process.

7. The layer stack according to claim 1, wherein the physical vapor deposition process is a sputtering process at a temperature of the protection layer of 350° C. or less.

8. The layer stack according to claim 1, wherein a thickness of at least one of the one or more metal oxide containing protection layers is less than 20 nm and less than a thickness of at least one of the one or more passivation layers.

9. The layer stack according to claim 1, wherein a thickness of the carrier layer is more than 40 nm and more than a thickness of at least one of the one or more passivation layers.

10. A solar cell comprising the layer stack according to claim 1; wherein the solar cell comprises a TOPCon-architecture.

11. The solar cell according to claim 10, wherein the carrier layer is a photovoltaic carrier layer comprising a bipolar semiconductor junction.

12. The solar cell according to claim 11, wherein the one or more passivation layers comprises a first passivation layer configured as an anti-reflection layer on a front side of the carrier layer, wherein the solar cell further comprises a metallization on the front side of the carrier layer.

13. The solar cell according to claim 12, wherein the one or more metal oxide containing protection layers comprise a first protection layer disposed between the anti-reflection layer and the carrier layer, wherein a first metal oxide containing protection layer of the one or more metal oxide containing protection layers physically contacts an emitter of the bipolar semiconductor junction and the anti-reflection layer.

14. The solar cell according to claim 10, wherein the one or more passivation layers comprises a second passivation layer configured as an anti-reflection layer on a rear side of the carrier layer.

15. The solar cell according to claim 14, wherein the dielectric tunnel oxide layer is disposed between the second passivation layer and the carrier layer; and wherein the dielectric tunnel oxide has a thickness of less than 20 nm.

16. The solar cell according to claim 15, further comprising a polycrystalline transfer layer between the dielectric tunnel oxide layer and the second passivation layer.

17. The solar cell according to claim 16, wherein the one or more metal oxide containing protection layers comprises a second metal oxide containing protection layer disposed between the second passivation layer and the carrier layer and physically contacts the transfer layer and the second passivation layer.

18. A process system comprising:
one or more vacuum chambers;
multiple process devices disposed in the one or more vacuum chambers, the multiple process devices being configured to provide a process sequence; wherein the process sequence of the multiple process devices comprises:
forming one or more passivation layers over the carrier layer via a physical vapor deposition process; and
forming, for each of the one or more passivation layers, a metal oxide containing protection layer between the passivation layer and the carrier layer via a chemical vapor deposition process; and
a transport device configured for transporting a substrate providing a carrier layer through the one or more vacuum chambers.

19. The process system according to claim 18, wherein the process sequence further comprises exposing the protection layer to an outgassing process prior to forming the passivation layer, wherein the outgassing process is configured to reduce a hydrogen content of the protection layer by annealing the protection layer.

20. The process system according to claim 18, wherein the process sequence is implemented in the absence of silane and in the absence of a plasma-enhanced chemical vapor deposition process.
